(19) United States
(12) Patent Application Publication
(10) Pub. No.: US 2025/0290975 A1
(43) Pub. Date: Sep. 18, 2025

(54) PROBER

(71) Applicant: TOKYO SEIMITSU CO., LTD., Tokyo (JP)

(72) Inventor: Takekiyo ICHIKAWA, Tokyo (JP)

(21) Appl. No.: 19/062,471

(22) Filed: Feb. 25, 2025

(30) Foreign Application Priority Data
Mar. 13, 2024 (JP) 2024-039162

(51) Int. Cl. G01R 31/28; G01R 1/073

(52) U.S. Cl. CPC G01R 31/2881; G01R 1/07314; G01R 31/2879

(57) ABSTRACT

A prober according to an embodiment tests the electrical characteristics of semiconductor devices formed on a wafer. The prober includes: a plurality of areas for each of which a set dew point for preventing dew condensation is set, the set dew points being different from each other; a supply unit that supplies dry gas to the respective areas; and a controller that controls supply of the dry gas from the supply unit. The controller controls supply of the dry gas to the respective areas so that dew points in the respective areas become the set dew points.

### CROSS REFERENCE TO RELATED APPLICATION

This application claims priority from Japanese Patent Application No. 2024-039162, filed on Mar. 13, 2024 in the Japan Patent Office, the contents of which being incorporated by reference herein in its entirety.

### BACKGROUND

The present invention relates to probers for testing devices formed on wafers.

A wafer on which a number of devices are formed through front-end processes of semiconductor manufacturing is divided into multiple chips of individual devices in a dicing process. Prior to the dicing process, probing is performed to remove defective devices from the devices on the wafer. Probing is wafer-level testing for testing the electrical characteristics of devices formed on each wafer to determine defective devices. A machine for probing is a prober (refer to JP 2018-049989A).

A prober includes a probe card of a plurality of probes. The probes are brought in electrical contact with a test head. A wafer is brought into contact with the probe card, so that the probes touch electrode pads of the devices. Electrical signals are sent from the test head to the devices via the probes to test the electrical characteristics so as to determine whether or not each device is a defective device.

As wafers are becoming larger in size and more highly integrated in recent years, the number of devices formed on one wafer is also increasing. There have therefore been demands for increasing throughput in semiconductor manufacturing and improving the efficiency of testing to reduce costs. In this regard, a so-called multi-stage prober in which a plurality of stages of multiple test heads arranged horizontally are provided in the up-down direction has been proposed. Such a prober can perform testing with a plurality of test heads simultaneously and continuously, which improves the efficiency of testing.

The aforementioned probing is performed in view of actual use environments in order to ensure the functionalities of the devices, and is therefore performed under low-temperature environments depending on the specifications of the devices. In such cases, in order to prevent devices from being destroyed by dew condensation, such measures as dry air purge on test areas to lower the dew point are taken.

In addition to test areas, however, it is also necessary to prevent dew condensation in areas in which electrical components are accommodated. There is also a concern that dew condensation may occur in the process of carrying a wafer after being tested. Dry air purge may be performed over the whole areas including conveyance areas in addition to test areas, but this results in consumption of large quantities of dry air and increase in costs. This problem will be particularly significant for multi-stage probers, which have a large number of areas.

### SUMMARY

The present invention has been made in view of the aforementioned circumstances, and one object thereof is to provide a prober capable of preventing dew condensation of wafers, etc. while reducing dry gas consumption.

An aspect of the present invention is a prober that tests the electrical characteristics of semiconductor devices formed on a wafer. The prober includes: a plurality of areas for each or which a set dew point for preventing dew condensation is set, the set dew points being different from each other; a supply unit that supplies dry gas to the respective areas; and a controller that controls supply of the dry gas from the supply unit. The controller controls supply of the dry gas to the respective areas so that dew points in the respective areas become the set dew points.

### BRIEF DESCRIPTION OF DRAWINGS

FIG. 1 is a diagram illustrating a schematic configuration of a prober according to an embodiment;

FIG. 2 is a horizontal sectional view schematically illustrating an internal structure of the prober;

FIG. 3 is a cross-sectional view taken along arrows A-A in FIG. 2;

FIG. 4 is an enlarged diagram of part B in FIG. 3;

FIG. 5 is a diagram illustrating a configuration of a measurement part;

FIG. 6 is a diagram illustrating operation of the measurement part;

FIG. 7 is a flowchart illustrating an outline of a probing process; and

FIG. 8 is a diagram schematically illustrating a configuration of a prober according to a modification.

### DETAILED DESCRIPTION

Some embodiments will now be described. The description is not intended to limit the scope of the invention, but to exemplify the invention.

Hereinafter, an embodiment of the present invention will be described with reference to the drawings. In the following embodiment and modifications thereof, components that are substantially the same will be designated by the same reference numerals and redundant description thereof may be omitted as appropriate.

A prober according to an embodiment tests the electrical characteristics of semiconductor devices (also simply referred to as “devices”) formed on each wafer. The prober includes a plurality of areas including a test area and a conveyance area. For probing (wafer-level testing) in a low-temperature environment, a dew point is set in advance in each of the areas to prevent dew condensation (the dew point set in each area will also be referred to as a “set dew point”).

For probing, dry air is supplied to each area at a flow rate depending on the set dew point. Specifically, when the set dew points in the areas are different from each other, the dry air is supplied at a higher purge flow rate as the set dew point is lower and at a lower purge flow rate as the set dew point is higher. Supply of necessary and sufficient dry air depending on the set dew point as described above enables prevention of dew condensation in the prober and saving of dry air being used. Details thereof will be described hereinafter.

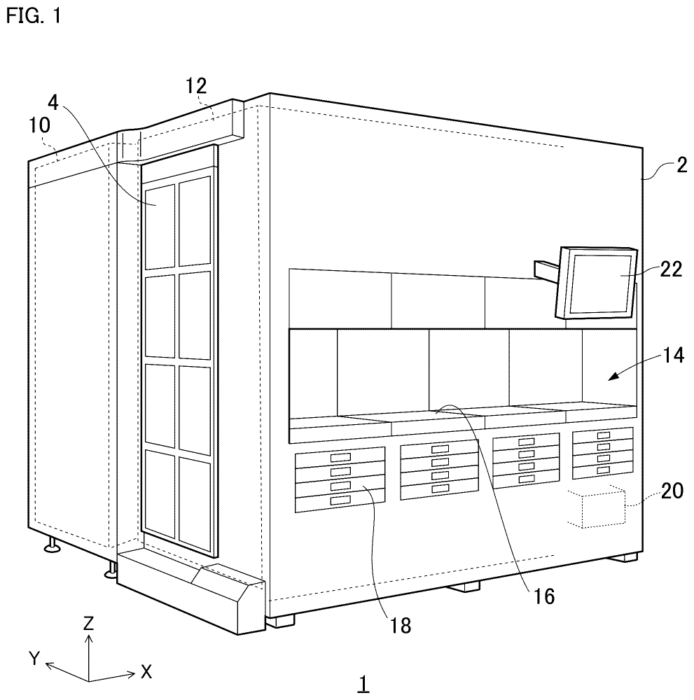

FIG. 1 is a diagram illustrating a schematic configuration of a prober according to an embodiment.

Hereinafter, for convenience of description, the left-right directions, the front-back directions, and the up-down directions when the machine is viewed from the front will be referred to as an X-axis direction, a Y-axis direction, and a Z-axis direction, respectively.

The prober 1 has a housing 2 having a rectangular shape in front view and in plan view. In the housing 2, a measurement area 10 in which each wafer is tested, and a loader area 12 through which wafers, etc. are conveyed into and from the measurement area 10 are located. The loader area 12 includes an accommodating area 14 in which wafers and probe cards are accommodated.

The accommodating area 14 includes a wafer storage part 16 for accommodating wafers and a card storage part 18 for accommodating probe cards. The wafer storage part 16 accepts wafer cassettes, such as FOUPs and FOSBs, accommodating a plurality of wafers. A worker or a robot can reach wafers or probe cards to be collected from the front side of the respective storages. A loader door 4 through which the worker goes into and out of the loader area is provided on a side face of the housing 2.

The prober 1 is also provided with a controller 20 and an operation panel 22. The controller 20 is constituted by a general-purpose computer including a CPU for executing various computation processes, a memory or a storage for storing control programs and the like, a memory to be used as a work area for data storage and program execution, an input/output interface, a user interface, and the like. The user interface receives operations input through the operation panel 22 by an operator. The controller 20 controls respective functional units (mechanisms and devices) of the prober 1 in accordance with control programs.

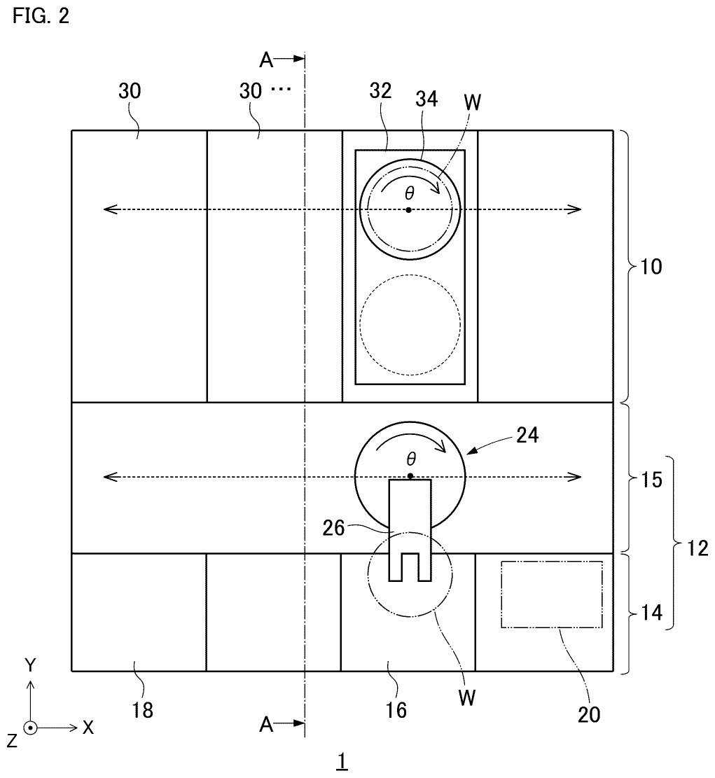

FIG. 2 is a horizontal sectional view schematically illustrating an internal structure of the prober 1.

The prober 1 includes the measurement area 10 and the loader area 12. The measurement area 10 includes the test area, which will be described later. The measurement area 10 and the loader area 12 are partitioned with a partition wall inside the housing 2. The loader area 12 includes the accommodating area 14 and a conveyance area 15. In the conveyance area 15, a conveyance unit 24 for conveying wafers W and probe cards (to be described later) is movably arranged.

In the measurement area 10, a plurality of measurement parts 30 for probing (wafer-level testing) of wafers W are installed. In the embodiment, a multi-stage prober in which three stages of four measurement parts 30 arranged horizontally are provided in the up-down direction is adopted. The number of horizontally arranged measurement parts 30 and the number of stages can be set as appropriate.

In the measurement area 10, an alignment unit 32 shared by the measurement parts 30 on all the stages. The alignment unit 32 detachably supports wafer chucks 34. Each wafer chuck 34 fixes a wafer W by sucking the wafer W with vacuum suction, for example, and is attached to and detached from a test head of a measurement part 30 in a probing process (details of which will be described later). The alignment unit 32 can move among the measurement parts 30 arranged horizontally. Each wafer chuck 34 is movable in X, Y, and Z directions within the measurement area 10 by the operation of the alignment unit 32 and is rotatable about an axis in the Z direction (in a direction θ).

The conveyance unit 24 conveys each wafer W between the wafer storage part 16 and each measurement part 30, and conveys each probe card between the card storage part 18 and each measurement part 30. The conveyance unit 24 has an arm 26 for passing each wafer W. The arm 26 has a suction pad, which is not illustrated, on an upper face thereof. The arm 26 holds a wafer W by vacuum suction of a rear face of the wafer W with the suction pad. The conveyance unit 24 is a conveyor shared by the measurement parts 30 on all the stages, being movable in the X direction and in the Z direction by the operation of a drive mechanism, which is not illustrated, and being rotatable about an axis in the Z direction (in the direction θ).

The conveyance unit 24 advances and retracts (extends and contracts) the arm 26 forward and backward by the operation of an arm driving mechanism, which is not illustrated. A wafer W in the wafer storage part 16 is taken out by the arm 26, and conveyed to a measurement part 30 by the conveyance unit 24. Furthermore, a wafer W after being tested is brought back to the wafer storage part 16 through a reversed path from a measurement part 30.

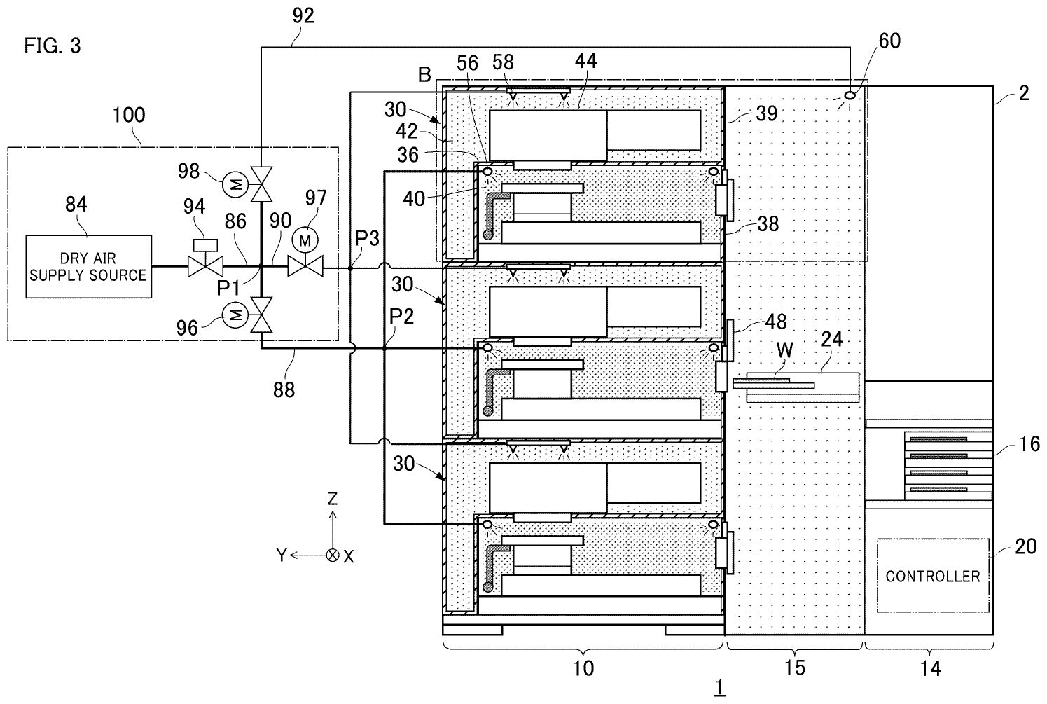

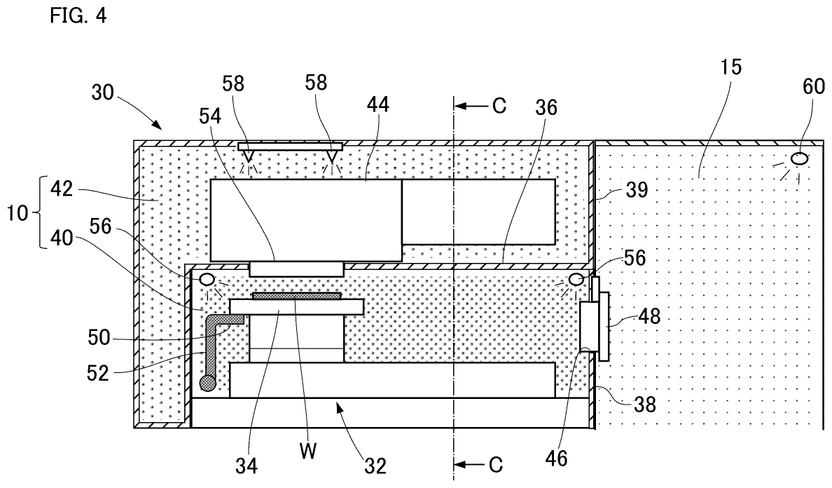

FIG. 3 is a cross-sectional view taken along arrows A-A in FIG. 2. FIG. 4 is an enlarged diagram of part B in FIG. 3.

As illustrated in FIG. 3, three stages of measurement parts 30 are provided in the up-down direction in the measurement area 10. Each measurement part 30 is defined by a partition 36 in a test area 40 and an equipment accommodating area 42. The test area 40 is an area in which a wafer W to be tested is placed, and is located at a relatively lower position. The equipment accommodating area 42 is an area in which a test head 44 and other electrical equipment are accommodated, and is located at a relatively higher position. The test area 40 is separated from the conveyance area 15 by a partition 38, and the equipment accommodating area 42 is separated from the conveyance area 15 by a partition 39. The equipment accommodating area 42 and the conveyance area 15 correspond to an “outer area” defined separately from the test area 40.

More specifically, as illustrated in FIG. 4, the alignment unit 32 is located in the test area 40. The partition 38 has an opening 46 through which the test area 40 and the conveyance area 15 communicate, and a shutter 48 for opening and closing the opening 46. When the shutter 48 is open, the arm 26 of the conveyance unit 24 can be advanced into the test area 40. That is, the wafer W can be passed between the conveyance unit 24 and the alignment unit 32.

In addition, in the test area 40, a heat exchanger 50 for cooling the wafer chuck 34 is located. A pipe 52 for circulation of a coolant is connected to the heat exchanger 50. In a case where probing is performed in a low-temperature environment, the coolant is supplied to the wafer chuck 34 through the pipe 52. This enables cooling of a wafer W (that is, devices formed on the wafer W) placed on the wafer chuck 34.

In the equipment accommodating area 42, the test head 44 and electrical equipment, which is not illustrated, are located. At a boundary between the test area 40 and the equipment accommodating area 42, a pogo frame 54 is arranged. The pogo frame 54 functions as an interface connecting the test head 44 with the probe card (to be described later).

In each area, a discharge part for discharging dry air for preventing dew condensation is provided. A discharge part 56 is provided in the test area 40, and a discharge part 58 is provided in the equipment accommodating area 42. A discharge part 60 is also provided in the conveyance area 15. The dew point necessary for preventing dew condensation varies among the areas. Thus, a set dew point is determined for each area and supply of dry air is controlled on the basis of the set dew point, details of which will be described later.

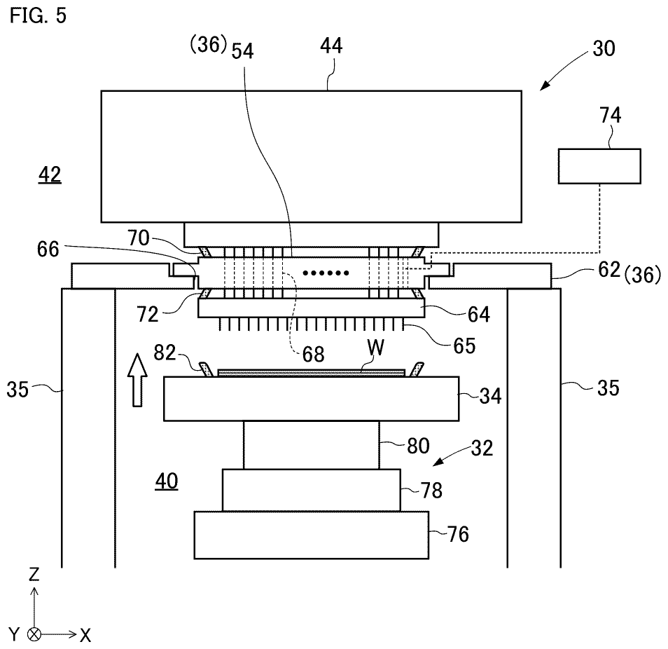

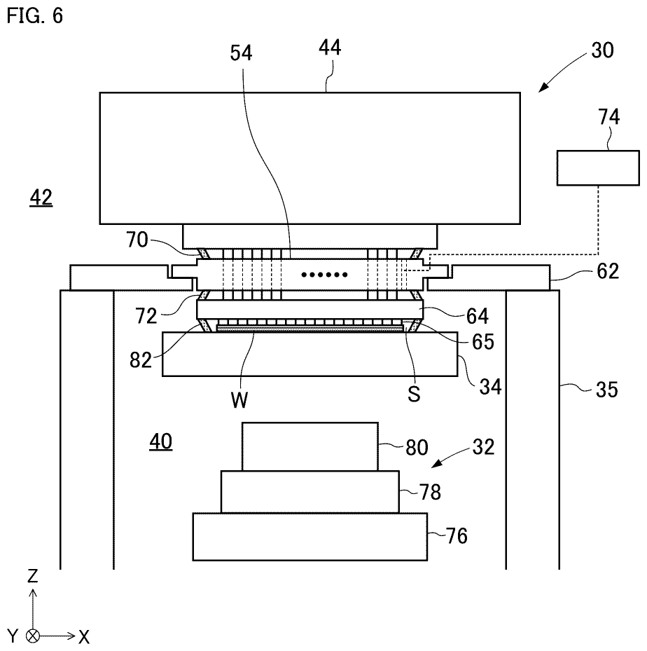

FIG. 5 is a diagram illustrating a configuration of a measurement part 30, and corresponding to a cross section along arrows C-C in FIG. 4. FIG. 6 is a diagram illustrating operation of the measurement part 30.

As illustrated in FIG. 5, each measurement part 30 includes a wafer chuck 34, a test head 44, a pogo frame 54, a head stage 62, and a probe card 64. The probe card 64 includes a number of probes 65 for supplying power to a wafer W.

The pogo frame 54 and the head stage 62 constitute part of the partition 36. The head stage 62 is supported by a support member 35. The head stage 62 has, at its center, a mounting hole 66 having a complementary shape (circular shape) for mounting the pogo frame 54. The pogo frame 54 is mounted to be fitted into the mounting hole 66, thus closing the mounting hole 66. The head stage 62 has a suction surface capable of sucking the pogo frame 54, and fixes the pogo frame 54 by sucking the pogo frame 54 with a suction device (a vacuum pump, for example), which is not illustrated. The boundary between the head stage 62 and the pogo frame 54 is kept airtight. In a modification, however, the head stage 62 and the pogo frame 54 may be fixed by a fixing structure such as screws.

The test head 44 is supported above the head stage 62. The test head 44 is electrically connected with the probes 65 of the probe card 64, supplies test signals (electrical signals) to respective devices on the wafer W during testing, and detects signals output from the respective devices to obtain electrical characteristics thereof. In this manner, whether the respective devices work properly is tested.

The pogo frame 54 has a number of pogo pins 68 for electrically connecting terminals formed on a lower face (a face facing the pogo frame 54) of the test head 44 with terminals formed on an upper face (a face facing the pogo frame 54) of the probe card 64. In addition, seal rings 70 and 72 are arranged on peripheral edges of an upper face (a face facing the test head 44) and a lower face (a face facing the probe card 64), respectively, of the pogo frame 54.

When a suction device 74 (a vacuum pump, for example) is activated, a space surrounded by the test head 44, the pogo frame 54, and the seal ring 70 and a space surrounded by the probe card 64, the pogo frame 54, and the seal ring 72 are reduced in pressure. As a result, the test head 44, the pogo frame 54, and the probe card 64 are integrated.

According to this configuration, an inner space (that is, the test area 40) and an outer space (that is, the equipment accommodating area 42) are separated from each other by the partition 36 including the head stage 62 and the pogo frame 54. Note that, in the embodiment, even when the probe card 64 is removed from the pogo frame 54 for replacement of the probe card 64, the function of the seal ring 70 maintains the airtightness between the test area 40 and the equipment accommodating area 42.

The probe card 64 has a plurality of probes 65 for electrodes of the respective devices on the wafer W to be tested. When the test head 44, the pogo frame 54, and the probe card 64 are integrated as described above, the probes 65 are electrically connected with the terminals of the test head 44 via the pogo frame 54. The probe card 64 includes a number of probes 65 for the electrodes of all the devices on the wafer W to be tested, and all the devices on the wafer W are simultaneously tested in the measurement part 30.

The wafer chuck 34 sucks to fix the wafer W by activating a suction device (a vacuum pump, for example), which is not illustrated. The wafer chuck 34 is detachably supported by the alignment unit 32. The alignment unit 32 includes an X table 76, a Y table 78, and a Z table 80.

A guide rail extending in the X direction is provided in the measurement area 10 of the housing 2, and the X table 76 is horizontally arranged to be movable in the X direction along the guide rail. The X table 76 is driven by a moving mechanism, which is not illustrated. A guide rail extending in the Y direction is provided on an upper face of the X table 76. The Y table 78 is horizontally arranged to be movable in the Y direction along the guide rail. The Y table 78 is driven by a moving mechanism, which is not illustrated. Each moving mechanism may be constituted by a feed screw mechanism and a servomotor that drives the feed screw mechanism, or may be constituted by a linear motor.

The Z table 80 is supported to be movable, up and down, in the Z direction and rotatable in the direction θ by the Y table 78. The Z table 80 is provided with a lifting mechanism for moving the wafer chuck 34 up and down and a rotating mechanism for rotating the wafer chuck 34 (which are not illustrated). The rotating mechanism is constituted by a spindle motor, for example. The wafer chuck 34 is detachably supported by an upper face of the Z table 80. This configuration allows the wafer chuck 34 to be moved in each of the X direction, the Y direction, the Z direction, and the direction θ. Movement of the wafer chuck 34 enables the wafer W to be positioned relative to the probe card 64.

Chuck sealing rubber 82 (a seal ring) is arranged to surround the wafer W on the upper face of the wafer chuck 34. In the probing process, as illustrated in FIG. 6, the Z table 80 is moved to move the wafer chuck 34 (up and down) toward the probe card 64. At this point, the chuck sealing rubber 82 comes in contact with the lower face of the probe card 64, and a space S surrounded by the wafer chuck 34, the probe card 64, and the chuck sealing rubber 82 is thus formed. A suction device (a vacuum pump, for example), which is not illustrated, is activated to reduce the pressure in the space S, and the wafer chuck 34 is therefore pulled toward the probe card 64. As a result, the probes 65 of the probe card 64 come into contact with the respective devices on the wafer W, and testing can be conducted.

At this point, the Z table 80 can be separated from the wafer chuck 34 as illustrated, so that the alignment unit 32 can be used for another measurement part 30. As described above, the alignment unit 32 is shared by the measurement parts 30 on all the stages, a wafer W can be passed in a measurement part 30 while testing is being performed in another measurement part 30.

The wafer chuck 34 has, in the inside thereof, a heating and cooling unit (not illustrated). This enables a wafer W to be in a high-temperature state (150° C., for example) or in a low-temperature state (−40° C., for example) for testing the electrical characteristics of devices on the wafer W. In the embodiment, a double layer structure including a heating layer of a planar heater and a cooling layer of a coolant passage is adopted as the heating and cooling unit. In a modification, a heater/cooler having a single layer structure in which a cooling pipe, around which a heater is wound, is embedded in a thermal conductor may be adopted as the heating and cooling unit.

Next, a configuration for preventing dew condensation in the embodiment will be described in detail.

The description refers back to FIG. 3, in which the prober 1 supplies a dry gas to the respective areas (purging) to prevent failure or breakage of an electronic component or electrical equipment inside the housing 2 due to dew condensation.

The prober 1 includes a supply unit 100 for supplying a dry gas to the respective areas. The supply unit 100 includes a dry air supply source 84, a gas supply passage 86, and a plurality of control valves (an on-off valve 94, and flow control valves 96 to 98). The gas supply passage 86 connects the discharge parts of the respective areas with the dry air supply source 84. The gas supply passage 86 branches into a first supply passage 88, a second supply passage 90, and a third supply passage 92 at a branching point P1. The first supply passage 88 further branches at a branching point P2 and connected with the discharge parts 56 in the test areas 40 of the respective measurement parts 30. The second supply passage 90 further branches at a branching point P3 and connected with the discharge parts 58 in the equipment accommodating areas 42 of the respective measurement parts 30. The third supply passage 92 is connected with the discharge part 60 in the conveyance area 15.

The dry air supply source 84 includes a tank for storing a pressurized dry gas. The on-off valve 94 is located upstream of the branching point P1 on the gas supply passage 86, and the flow control valve 96 is located upstream of the branching point P2 on the first supply passage 88. The flow control valve 97 is located upstream of the branching point P3 on the second supply passage 90, and the flow control valve 98 is located on the third supply passage 92. The on-off valve 94 is a solenoid-operated electromagnetic valve in the embodiment, but may alternatively be a motor-operated valve. The flow control valves 96 to 98 are motor-operated valves in the embodiment, but may alternatively be electromagnetic valves.

The controller 20 controls supply of the dry gas from the supply unit 100. The controller 20 opens the on-off valve 94 before performing the probing process, and controls the opening degrees of the flow control valves 96 to 98 on the basis of the set dew points in the respective areas. This controls the flow rates of the dry air supplied to the respective areas to make the temperatures in the areas closer to the set dew points.

Specifically, regarding the temperature environment during probing, the lowest temperature that can be reached in each area will be referred to as a “required dew point”. In a case where each area is filled with normal air (atmosphere), dew condensation can occur when the temperature in the area becomes lower than the required dew point. A temperature lower than the required dew point by a predetermined degree is therefore set in advance as the “set dew point” for each area. This allows the set dew point to have a margin in order to reliably prevent dew condensation. The predetermined degree (also referred to as a “dew point margin”) can be appropriately set for each area in accordance with the environment in which the prober 1 installed, factors with which temperature changes, such as the inflow and outflow amounts of dry gas and time, and the like. Alternatively, the dew point in the installation environment may be fed back by using a dew point sensor (not illustrated) installed in the installation environment, so that the inflow and outflow amounts can be controlled and the dew point margin can be appropriately set for each area. The set dew point is lower than the required dew point by the dew point margin.

In the test area 40, it is particularly necessary to prevent dew condensation on devices on a wafer W, and the wafer W is cooled to −40° C. during probing on the basis of the specifications of the devices. As described above, this temperature is achieved by cooling the wafer chuck 34 with the coolant. In the test area 40, while the required dew point is −40° C., the dew point margin is set to 10° C. because the dew point tends to increase through opening and closing of the shutter 48, and the set dew point is therefore −50° C.

In the equipment accommodating area 42, the test head 44 and other electrical components are located, and it is therefore necessary to prevent dew condensation on these components. There are, however, heat conduction and heat transfer from the test area 40 to the equipment accommodating area 42. The lowest temperature is therefore estimated to reach −5° C. In the equipment accommodating area 42, however, unlike the test area 40, no shutter is opened or closed, and the dew point increase is therefore small. Thus, in the equipment accommodating area 42, the required dew point is −5° C., the dew point margin is set to 5° C., and the set dew point is therefore −10° C.

In the conveyance area 15, the number of electrical components is small, but it is necessary to prevent dew condensation in the process of conveying a wafer W after being tested. In view of the installation environment of the prober 1, the lowest temperature in the conveyance area 15 is estimated to be +15° C. In the conveyance area 15, however, the dew point is likely to increase because the conveyance area 15 has a larger volume than the test area 40 and the equipment accommodating area 42. Thus, in the conveyance area 15, while the required dew point is +15° C., the dew point margin is set to 10° C. and the set dew point is therefore +5° C.

For performing the probing process, the controller 20 controls the opening degrees of the flow control valves 96 to 98 and controls the flow rates of dry air supplied to the respective areas so that the dew points therein become the set dew points that are set for the respective areas.

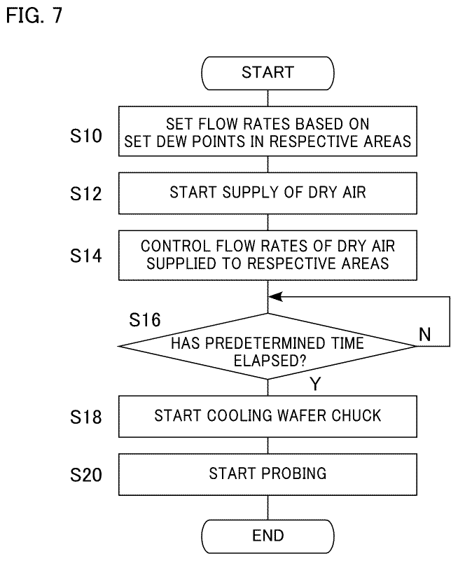

FIG. 7 is a flowchart illustrating an outline of the probing process.

In the probing process, the controller 20 sets the flow rates of dry air to be supplied to the respective areas on the basis of the set dew points in the respective areas (S10). Subsequently, the controller 20 opens the on-off valve 94 to start supply of dry air (S12), and controls the opening degrees of the flow control valves 96 to 98 to control the flow rates of dry air supplied to the respective areas (S14).

When a preset time, in which the dew point in each areas is estimated to reach the set dew point, has elapsed (Y in S16), the controller 20 starts cooling the wafer chuck 34 (S18), and then starts probing (S20). The “preset time” is set in advance on the basis of experiments or the like.

As described above, in the embodiment, the set dew points in the test area 40, the equipment accommodating area 42, and the conveyance area 15 are different from each other. Then, during probing, dry air is supplied to the respective areas at the flow rates depending on the set dew points. Specifically, supply of necessary and sufficient dry air depending on the set dew points to the respective areas enables prevention of dew condensation in the respective areas while reducing consumption of dry air.

In addition, because dry air is supplied separately to a plurality of areas, the independence of the individual areas can be ensured. Thus, the opening and closing of the shutter 48 when a wafer W is carried into and out from the test area 40 have a low impact on the environment (temperature, humidity, etc.) in the equipment accommodating area 42. A worker may open the loader door 4 to go into and out of the conveyance area 15 for maintenance of the conveyance unit 24 or the like. Because, however, the test area 40 is separated from the conveyance area 15, an increase in the dew point in the test area 40 can be suppressed. In this manner, because it becomes less necessary to consider the dew point when performing maintenance, the efficiency of maintenance itself is improved.

Furthermore, because the test area 40 is an area separate from the equipment accommodating area 42, the volume of the test area 40 can be kept to the minimum necessary. The dew point therefore quickly recovers after a wafer W is carried into or out from the test area 40, which increases the efficiency (throughput) of the probing process.

A certain embodiment has been described above. It should be obvious that the present invention is not limited to the embodiment and various modifications could be further developed within the technical idea underlying the present invention.

### MODIFICATIONS

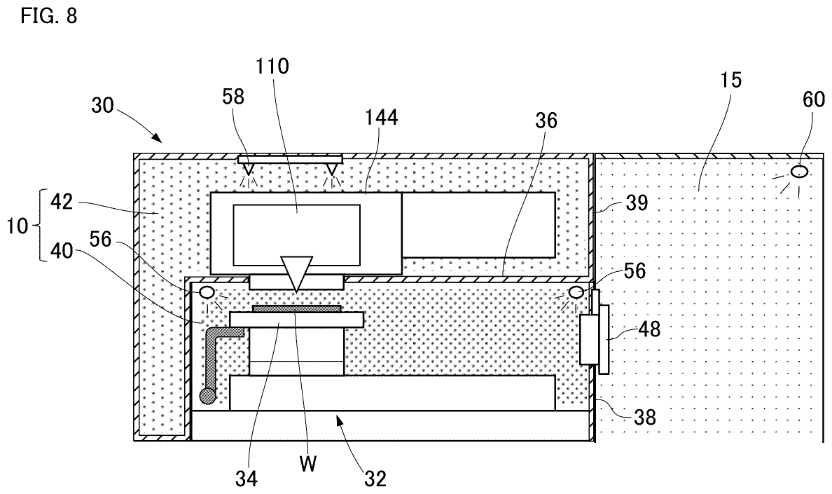

FIG. 8 is a diagram schematically illustrating a configuration of a prober according to a modification.

Although not mentioned in the embodiment, the structure of partitioned areas may be used for protection (dew condensation prevention) of equipment for observation during testing. In the prober according to the modification, a dummy test head 144 in some of a plurality of equipment accommodating areas 42, and a microscope 110 is accommodated in the test head 144. The microscope 110 is equipment for precisely observing the position of a wafer W on the wafer chuck 34.

The test head 144 is a housing similar to the test head 44 but without the internal structure thereof, and has an opening through which a lens of the microscope 110 is exposed downward (toward the wafer W). To achieve airtightness between the test area 40 and the equipment accommodating area 42, a transparent (translucent) partition plate is arranged at a position of the partition 36 corresponding to the position of the lens of the microscope 110.

This configuration allows observation of positional precision of a wafer W on the wafer chuck 34 with the microscope 110. Because no shutter 48 is present in the equipment accommodating area 42, unlike the test area 40, and the equipment accommodating area 42 is not opened toward the conveyance area 15, entry of external atmosphere to the equipment accommodating area 42 can be prevented. Thus, because a change in the dew point in the area is small and loss of transparency of (dew condensation on) the lens is prevented, the condition of the microscope 110 can be stably maintained.

While the microscope is presented as an example of an optical instrument accommodated in the equipment accommodating area 42 in this modification, other optical instruments such as a camera may be accommodated. Alternatively, a temperature measuring instrument such as a thermosensor for detecting the temperature of a wafer W may be accommodated. Any equipment for maintenance of devices or members located in the test area 40 may be accommodated. The low dew-point space in the equipment accommodating area 42 can also be used for such equipment.

### OTHER MODIFICATIONS

While an example in which dry air is used as the dry gas has been presented in the embodiment, a dry inert gas or other dry gases may be used. Dry air may be supplied to the loader area 12 (conveyance area 15) into which a worker may enter and another dry gas may be supplied to the measurement area 10 (at least one of the test area 40 and the equipment accommodating area 42). Different dry gases may be used depending on the set dew points.

In the embodiment, an example in which the flow rates of the dry gas supplied to the respective areas are controlled so that the dew points become the set dew points in the respective areas has been presented. In a modification, dry gases with different cooling performances (cooling efficiencies) (different kinds of dry gases) may be supplied in accordance with the set dew points. Specifically, a dry gas with relatively higher cooling performance may be supplied to an area with a lower set dew point, and a dry gas with relatively lower cooling performance may be supplied to an area with a higher set dew point. In this case, the flow rates of dry gases supplied to the respective areas may be equal to or different from each other.

While an example of the multi-stage prober including a plurality of measurement parts 30 has been presented in the embodiment, a single-stage prober including a single measurement part 30 may be used. In this case, in a manner similar to the embodiment, the controller controls the flow rates of dry gas so that the dew points become the set dew points in the respective areas.

While measures against dew condensation on a wafer W has been mainly described in the embodiment, the probe card 64, which is a consumable supply, needs timely replacing. Specifically, each probe card 64 is also carried into and out from the test area 40. In this regard, a dew condensation prevention effect similar to that in the case of the wafer W can also be produced according to the embodiment.

Although not mentioned in the embodiment, a structure capable of pulling out the test head 44 from the equipment accommodating area 42 may be adopted. For example, a structure in which a side wall of the partition 36 forming the equipment accommodating area 42 has a shutter and the test head 44 can be pulled out horizontally when the shutter is open may be adopted. This structure allows replacement of the test head 44 and the dummy test head 144 as described above with each other where appropriate. In addition, this structure facilitates maintenance of the test head 44. Because the test area 40 and the equipment accommodating area 42 are separate areas, getting the test heads in and out in this manner has a low impact on the dew point environment of the test area 40.

While probing mainly in a low-temperature environment has been described in the embodiment, it is needless to say that testing can also be performed at a plurality of temperature levels from a low temperature to a high temperature. After placement of a wafer W in the test area 40 is completed, the shutter 48 is closed, which allows the set temperature of the wafer chuck 34 to be changed regardless of heat exchanged with external air. This facilitates testing at a plurality of set temperatures.

The present invention is not limited to the embodiments described above and modifications thereof, and any component thereof may be modified and embodied without departing from the scope of the invention. Components described in the embodiments and modifications may be combined as appropriate to form various embodiments. Some components may be omitted from the components presented in the embodiments and modifications.

What is claimed is:

1. A prober that tests electrical characteristics of semiconductor devices formed on a wafer, the prober comprising:
a plurality of areas for each of which a set dew point for preventing dew condensation is set, the set dew points being different from each other;
a supply unit that supplies dry gas to the respective areas; and
a controller that controls supply of the dry gas from the supply unit,
wherein the controller controls supply of the dry gas to the respective areas so that dew points in the respective areas become the set dew points.

2. The prober according to claim 1, wherein the controller controls flow rates of the dry gas supplied to the respective areas so that the dew points are maintained at the set dew points in the respective areas.

3. The prober according to claim 1, wherein each of the set dew points is set to be lower than a lowest temperature in the corresponding area.

4. The prober according to claim 1,
wherein the plurality of areas include a test area in which the wafer and a probe card are placed and an outer area defined separately from the test area, and
wherein the controller controls supply of the dry gas to the respective areas on the basis of the set dew points for the test area and the outer area.

5. The prober according to claim 4, wherein the outer area includes an equipment accommodating area in which a test head to be connected with the probe card is located.

6. The prober according to claim 5, wherein a set dew point for the equipment accommodating area is higher than a set dew point for the test area.

7. The prober according to claim 6,
wherein the outer area includes a conveyance area defined separately from the equipment accommodating area, a conveyor for carrying the wafer into and out from the test area being located in the conveyance area, and
wherein a set dew point for the conveyance area is higher than the set dew point for the equipment accommodating area.

8. The prober according to claim 4,
wherein the outer area includes a conveyance area in which a conveyor for carrying the wafer into and out from the test area is located, and
wherein a set dew point for the conveyance area is higher than a set dew point for the test area.
